(19) United States
(12) Patent Application Publication
(10) Pub. No.: US 2009/0170334 A1
(43) Pub. Date: Jul. 2, 2009

(54) Copper Discoloration Prevention Following Bevel Etch Process

(76) Inventors: Tong Fang, Palo Alto, CA (US); Andrew D. Bailey, III, Pleasanton, PA (US); Yunsang Kim, Monte Sereno, CA (US); Olivier Rigoutat, Bethel, CT (US); George Stojakovic, Wappingers Falls, NY (US)

Correspondence Address: BUCHANAN, INGERSOLL & ROONEY PC, POST OFFICE BOX 1404, ALEXANDRIA, VA, 22313-1404, US

(21) Appl. No.: 12/341,384

(22) Filed: Dec. 22, 2008

Related U.S. Application Data
(60) Provisional application No. 61/009,142, filed on Dec. 27, 2007.

(51) Int. Cl. H01L 21/3065

(52) U.S. Cl. 438/710; 257/E21.218

(57) ABSTRACT

A method of bevel edge etching a semiconductor substrate having exposed copper surfaces with a fluorine-containing plasma in a bevel etcher in which the semiconductor substrate is supported on a semiconductor substrate support comprises bevel edge etching the semiconductor substrate with the fluorine-containing plasma in the bevel etcher; evacuating the bevel etcher after the bevel edge etching is completed; flowing defluorinating gas into the bevel etcher; energizing the defluorinating gas into a defluorination plasma at a periphery of the semiconductor substrate; and processing the semiconductor substrate with the defluorination plasma under conditions to prevent discoloration of the exposed copper surfaces of the semiconductor substrate upon exposure, the discoloration occurring upon prolonged exposure to air.

### CROSS-REFERENCE TO RELATED APPLICATIONS

This application claims priority under 35 U.S.C. 119 to U.S. Provisional Application No. 61/009,142 entitled COPPER DISCOLORATION PREVENTION FOLLOWING BEVEL ETCH PROCESS and filed on Dec. 27, 2008, the entire content of which is hereby incorporated by reference.

### SUMMARY

Provided is a method of bevel edge etching a semiconductor substrate having exposed copper surfaces with a fluorine-containing plasma in a bevel etcher in which the semiconductor substrate is supported on a semiconductor substrate support. The method comprises bevel edge etching the semiconductor substrate with the fluorine-containing plasma in the bevel etcher; evacuating the bevel etcher after the bevel edge etching is completed; flowing defluorinating gas into the bevel etcher; energizing the defluorinating gas into a defluorination plasma at a periphery of the semiconductor substrate; and processing the semiconductor substrate with the defluorination plasma under conditions to prevent discoloration of the exposed copper surfaces of the semiconductor substrate, the discoloration occurring upon prolonged exposure to air.

### BRIEF DESCRIPTION OF THE DRAWINGS

FIG. 1 is a schematic cross sectional diagram of a bevel etcher in accordance with an embodiment.

FIG. 2 is a graph showing atomic oxygen content on a copper surface of a semiconductor wafer as a function of the wafer radius after NF₃/CO₂ bevel etch processing, N₂—H₂/He processing, and exposure to air for more than seventy-two hours.

### DETAILED DESCRIPTION

Bevel clean modules (bevel etchers), for example, the 2300 Bevel Clean™ product manufactured by Lam Research Corporation, Fremont, Calif., remove films on the edge of a wafer using edge confined plasma technology. For 65 nm technologies and below, a primary source of device yield limiters are coming from defects transferred from the wafer edge. During device patterning, complex interactions of film deposition, lithography, etching and chemical mechanical polishing result in a wide range of unstable film stacks on the wafer edge. In subsequent steps, these film layers can produce defects that are transported to the device area of the wafer. Removal of these films at select points in the integration flow results in reduced defects and higher device yields. Accordingly, edge confined plasma provides control of the wafer edge buildup at multiple steps during the device fabrication process.

Bevel etched wafers containing exposed copper (Cu) surfaces can exhibit discoloration following bevel etching and exposure to air. Discoloration usually occurs within an hour of exposure to air. Queue-time for wafers between processing steps, during which time the wafers are often stored in a cassette and exposed to air, is usually less than about eight hours, for example, about two hours. However, during semiconductor processing, it is possible that as a result of production delays due to unavailability of equipment or breakdown, cassettes of wafers may be left in atmospheric air for longer times such as eight to twenty-four hours or longer.

Plasma processing in a bevel etcher 200, for example, to remove bevel edge build-up from a semiconductor substrate having exposed copper surface regions (e.g., physical vapor deposition copper surface), can comprise etching the bevel edge with a fluorine-containing plasma. The semiconductor substrate may comprise, for example, a wafer made with a copper Back-End-Of-the-Line (BEOL) damascene process. The semiconductor substrate may have a diameter of about 300 mm. The semiconductor substrate may comprise a bevel edge portion (e.g., about two mm wide) that surrounds multilayer integrated circuit (IC) device structures containing exposed copper inwardly of the bevel edge. The exposed copper surfaces may comprise copper surfaces on tantalum-containing seed layers across the wafer.

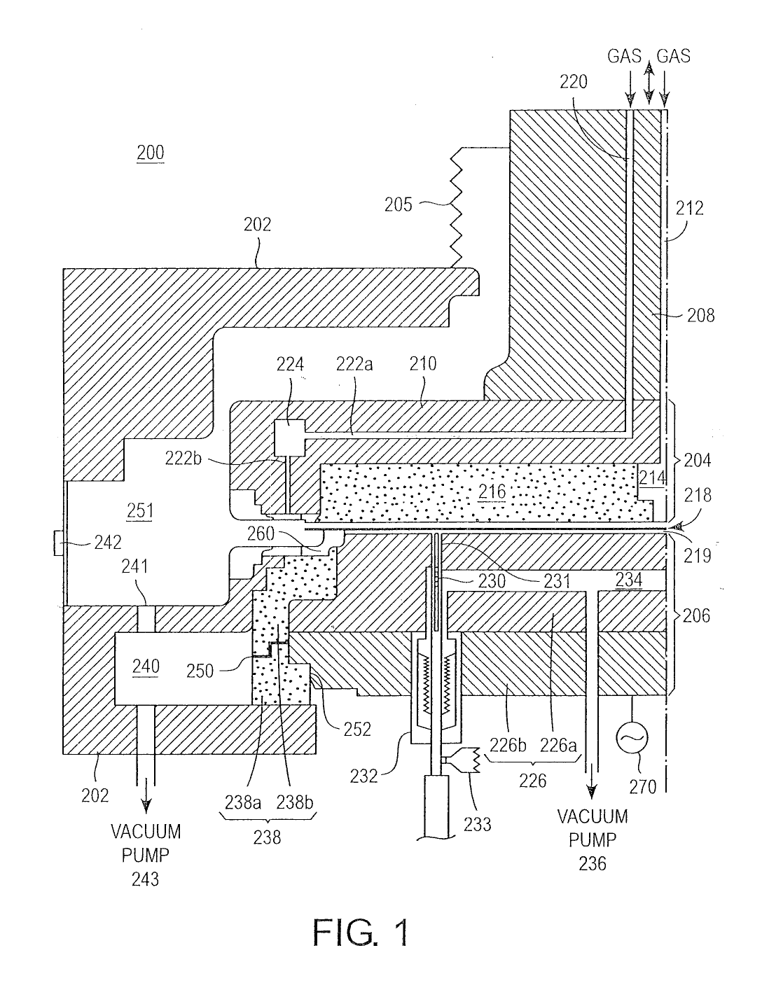

Referring now to FIG. 1, there is shown a schematic cross sectional diagram of a substrate etching system or bevel etcher 200 for cleaning the bevel edge of a substrate 218 in accordance with one embodiment, as disclosed in commonly assigned U.S. Patent Application Pub. No. 2008/0182412.

While an embodiment of a bevel etcher is shown in FIG. 1, the post bevel etch process described herein can be performed in any suitable bevel etch equipment. The bevel etcher 200 has a generally, but not limited to, axisymmetric shape and, for brevity, only half of the side cross sectional view is shown in FIG. 1. As depicted, the bevel etcher 200 includes: a chamber wall 202 having a door or gate 242 through which the substrate 218 is loaded/unloaded; an upper electrode assembly 204; a support 208 from which the upper electrode assembly 204 is suspended; and a lower electrode assembly 206. A precision driving mechanism (not shown in FIG. 1) is attached to the support 208 for moving upper electrode assembly 204 up and down (in the direction of the double arrow) so that the gap between the upper electrode assembly 204 and the substrate 218 is controlled accurately.

Metal bellows 205 are used to form a vacuum seal between the chamber wall 202 and support 208 while allowing the support 208 to have a vertical motion relative to the chamber wall 202. The support 208 has a center gas feed (passage) 212 and an edge gas feed (passage) 220. One or both gas feeds 212, 220 can deliver process gas to be energized into plasma to clean the bevel edge. During operation, the plasma is formed around the bevel edge of the substrate 218 and has a generally ring shape. To prevent the plasma from reaching the central portion of the substrate 218, the space between an insulator plate 216 on the upper electrode assembly 204 and the substrate 218 is small and the process gas is fed from the center feed, in an embodiment through a stepped hole 214. Then, the gas passes through the gap between the upper electrode assembly 204 and the substrate 218 in the radial direction of the substrate. Each gas feed is used to provide the same process gas or other gases, such as purge gas. For instance, the purge gas can be injected through the center gas feed 212, while the process gas can be injected through the edge gas feed 220. The plasma/process gas is withdrawn from the chamber space 251 to the bottom space 240 via a plurality of holes (outlets) 241. During a bevel cleaning operation, the chamber pressure is typically in the range of 500 mTorr to 2 Torr, e.g., a vacuum pump 243 can be used to evacuate the bottom space 240 during a cleaning operation.

The process gas can comprise an oxygen-containing gas, such as O₂ and/or CO₂. Fluorine-containing gas, such as, for example, NF₃, CF₄, SF₆, and/or C₂F₆, can also be added to the process gas. The amount of fluorine-containing gas in the process gas can depend on the specific film(s) being removed by bevel (edge) etching. For example, small amounts, such as <10% by volume, or large amounts, such as >80% or >90% by volume, of fluorine-containing gas can be present in the process gas. In different embodiments, the process gas can comprise, for example, about 5% by volume NF₃/balance CO₂ or about 10% by volume CF₄/balance CO₂.

The upper electrode assembly 204 includes: an upper dielectric plate or upper dielectric component 216; and an upper metal component 210 secured to the support 208 by a suitable fastening mechanism and grounded via the support 208. The upper metal component 210 is formed of a metal, such as aluminum, and may be anodized. The upper metal component 210 has one or more edge gas passageways or through holes 222a, 222b and an edge gas plenum 224, wherein the edge gas passageways or through holes 222a, 222b are coupled to the edge gas feed 220 for fluid communication during operation. The upper dielectric plate 216 is attached to the upper metal component 210 and formed of a dielectric material, for example, ceramic. If desired, the upper dielectric plate 216 may have a coating of Y₂O₃. Typically, it is difficult to drill a deep straight hole in some ceramics, such as Al₂O₃, and therefore a stepped hole 214 can be used instead of a deep straight hole. While the upper dielectric plate 216 is shown with a single center hole, the upper dielectric plate 216 may have any suitable number of outlets, e.g., the outlets can be arranged in a showerhead hole pattern if desired.

The lower electrode assembly 206 includes: powered electrode 226 having an upper portion 226a and a lower portion 226b and optionally operative to function as a vacuum chuck to hold the substrate 218 in place during operation; lift pins 230 for moving the substrate 218 up and down; a pin operating unit 232; bottom dielectric ring 238 having an upper portion 238a and a lower portion 238b. In an embodiment, the chuck can be an electrostatic chuck. Hereinafter, the term powered electrode refers to one or both of the upper and lower portions 226a, 226b. Likewise, the term bottom dielectric ring 238 refers to one or both of the upper and lower portions 238a, 238b. The powered electrode 226 is coupled to a radio frequency (RF) power source 270 to receive RF power during operation.

The lift pins 230 move vertically within cylindrical holes or paths 231 and are moved between upper and lower positions by the pin operating unit 232 positioned in the powered electrode 226. The pin operating unit 232 includes a housing around each lift pin to maintain a vacuum sealed environment around the pins. The pin operating unit 232 includes any suitable lift pin mechanism, such as a robot arm 233 (e.g., a horizontal arm having segments extending into each housing and attached to each pin) and an arm actuating device (not shown in FIG. 1). For brevity, only a tip portion of a segment of the robot arm is shown in FIG. 1. While three or four lift pins can be used to lift a wafer, such as, for example, a 300 mm wafer, any suitable number of lift pins 230 may be used in the bevel etcher 200. Also, any suitable mechanisms, such as lifter bellows, can be used as the pin operating unit 232.

The substrate 218 is mounted on a lower configurable plasma-exclusion-zone (PEZ) ring 260, wherein the term PEZ refers to a radial distance from the center of the substrate to the outer edge of the area where the plasma for cleaning the bevel edge is to be excluded. In an embodiment, the top surface of the powered electrode 226, the bottom surface of the substrate 218, and inner periphery of the lower configurable PEZ ring 260 can form an enclosed vacuum region recess (vacuum region) 219 in fluid communication with a vacuum source such as a vacuum pump 236. The cylindrical holes or paths for the lift pins 230 are also shared as gas passageways, through which the vacuum pump 236 evacuates the vacuum region 219 during operation. The powered electrode 226a includes a plenum 234 to reduce temporal pressure fluctuations in the vacuum region 219 and, in cases where multiple lift pins are used, to provide a uniform suction rate for the cylindrical holes.

On the top surface of the substrate 218 are integrated circuits, which can contain exposed copper surfaces which may be on tantalum-containing seed layers, formed by a series of processes. One or more of the processes may be performed by use of plasma that may transfer heat energy to the substrate, developing thermal stress on the substrate and thereby causing wafer bowing. During a bevel cleaning operation, the substrate bowing can be reduced by use of a pressure difference between the top and bottom surfaces of the substrate 218. The pressure in the vacuum region 219 is maintained under vacuum during operation by a vacuum pump 236 coupled to the plenum 234. By adjusting the gap between the upper dielectric plate 216 and the top surface of the substrate 218, the gas pressure in the gap can be varied without changing the overall flow rate of the process gas(es). Thus, by controlling the gas pressure in the gap, the pressure difference between the top and bottom surfaces of the substrate 218 can be varied and thereby the bending force applied on the substrate 218 can be controlled.

The bottom dielectric ring 238a, 238b is formed of a dielectric material, such as ceramic including Al₂O₃, and electrically separates the powered electrode 226 from the chamber wall 202. The lower portion 238b of the bottom dielectric ring in an embodiment has a step 252 formed on the inner periphery of its upper surface to mate with a recess on a lower edge of the powered electrode 226. The lower portion 238b in an embodiment has a step 250 formed on its outer periphery to mate with a stepped surface on the upper portion 238a of the bottom dielectric ring, referred to as a focus ring. The steps 250, 252 align the bottom dielectric ring 238 with the powered electrode 226. The step 250 also forms a tortuous gap along the surface thereof to eliminate the direct line-of-sight between the powered electrode 226 and the chamber wall 202 thereby reducing the possibility of a secondary plasma strike between the powered electrode 226 and the chamber wall 202.

The bevel edge cleaning plasma processing can comprise feeding a gas mixture including, for example, NF₃ or CF₄ into the bevel etcher and energizing the gas mixture into a plasma state. In particular, the gas mixture may comprise NF₃ and CO₂ or CF₄ and CO₂. For example, the gas mixture may comprise about 5% by volume NF₃/balance CO₂ or about 10% by volume CF₄/balance CO₂. The gas mixture may be fed into the bevel etcher at a periphery and/or at the center of the semiconductor substrate. For example, when the fluorine-containing gas mixture is fed into the bevel etcher at a periphery of the semiconductor substrate, N₂ gas may be fed into the bevel etcher at a center of the semiconductor substrate.

Bevel etching using a fluorine-containing plasma can result in discoloration of the semiconductor substrate copper surface, most noticeable at the periphery of the wafer, perhaps due to fluorine radicals on the copper surface causing accelerated oxidation when the copper surface is exposed to air. For example, a NF₃/CO₂ bevel etch process may exhibit discoloration on the wafer surface, in particular, on an outer annular surface zone near the periphery of the semiconductor. In particular, when NF₃/CO₂ bevel etch gas mixture is fed into the bevel etcher at a periphery of the semiconductor substrate, less severe discoloration (e.g., on an outer annular surface zone near the periphery of the substrate) has been observed as compared to when NF₃/CO₂ bevel etch gas mixture is fed into the bevel etcher at the center of the semiconductor substrate.

Discoloration of a semiconductor substrate copper surface upon exposure to ambient air for an hour or more can be prevented using a post bevel etch treatment with a defluorination plasma. In particular, an in situ N₂—H₂(He) plasma process can eliminate copper discoloration. Following bevel edge etching, depending on the semiconductor substrate and the bevel edge etching conditions, discoloration may appear on the semiconductor substrate copper surface within a few minutes (e.g., two to three minutes or fifteen minutes) of exposure to ambient air. However, should discoloration occur, it usually appears within an hour of exposure to air.

Without wishing to be bound by any theories, it is believed that discoloration of the copper surface may be related to copper oxidation accelerated by fluorine on the copper surface. Specifically, it is believed that bevel etching with the fluorine-containing plasma results in fluorine residue on the copper surface. During bevel edge cleaning fluorine-containing gas is energized into a fluorine-containing plasma at a periphery of the semiconductor substrate. Fluorine radicals on exposed copper surfaces on a semiconductor surface change the copper surface to a hydrophilic surface, which absorbs moisture easily. Thus, exposure to atmospheric air having moisture therein can cause discoloration of the copper surfaces due to oxidation.

It is further believed that hydrogen radicals in the defluorination plasma of the post etch treatment can react with fluorine on the copper surface and liberate fluorine from the copper surface, thus preventing accelerated oxidation and consequent discoloration of the copper surface (i.e., upon exposure to air). Thus, processing the semiconductor substrate with the defluorination plasma can remove fluorine radicals by exposing the copper surface to, for example, hydrogen radicals from the defluorination plasma. Defluorinating gas is energized into a defluorination plasma at a periphery of the semiconductor substrate during generation of plasma at the bevel edge. Hydrogen radicals can reduce F—Cu to Cu by forming gaseous HF, which can change the copper surface back to a hydrophobic surface, which repels moisture. Fluorine liberated from the copper surface, for example, in the form of volatile HF, is removed from the bevel etcher during the post etch treatment.

Accordingly, a method of preventing discoloration of a semiconductor substrate having a copper surface following etching with a fluorine-containing plasma in a bevel etcher comprises evacuating the bevel etcher after the bevel edge etching is completed, introducing defluorinating gas into the bevel etcher and energizing the defluorinating gas into a defluorination plasma at a periphery of the semiconductor substrate. The periphery of the semiconductor substrate is processed with the defluorination plasma for greater than about 5 seconds, the defluorination plasma is evacuated from the bevel etcher, and the substrate is removed from the bevel etcher for further processing.

The defluorinating gas of the post etch treatment can include, for example, hydrogen, and can also include, for example, nitrogen and/or carbon. For example, the defluorinating gas may comprise H₂, NH₃, and/or CHₓ, where x is 1-8. The defluorinating gas of the post etch treatment is fluorine-free and oxygen-free, i.e., it does not include fluorine or oxygen, and can be mixed with an inert gas, such as, for example, nitrogen, argon, helium, xenon, and/or krypton. The defluorinating gas is a post etch gas or copper passivation gas mixture. About 10-2000 sccm of the defluorinating gas can be flowed into the bevel etcher. More specifically, a gas mixture of about 100-400 sccm of N₂, for example about 150-250 sccm of N₂ or 200 sccm of N₂, and about 200-1000 sccm of defluorinating gas, for example, about 450-550 sccm of defluorinating gas or 500 sccm of defluorinating gas (e.g., about 2-10% H₂ in He carrier gas or 4% H₂ in He carrier gas), can be flowed into the bevel etcher. The defluorinating gas can also be flowed into the bevel etcher at a center of the semiconductor substrate. Specifically, if the post etch gas is fed from the center and edge gas feeds, 20 to 80 volume %, for example, 50 volume %, of the defluorinating gas can be flowed into the bevel etcher at a periphery of the semiconductor substrate and 20 to 80 volume %, for example, 50 volume %, of the defluorinating gas can be flowed into the bevel etcher at a center of the semiconductor substrate. When defluorinating gas is flowed into the bevel etcher only at a center of the semiconductor substrate, defluorinating gas is flowed from the center of the semiconductor substrate radially towards the periphery of the semiconductor substrate. It is believed that hydrogen radicals in the defluorination plasma of the post etch treatment can react with fluorine on the copper surfaces and liberate fluorine from the copper surfaces, thus preventing accelerated oxidation and consequent discoloration of the copper surfaces (i.e., upon exposure to air).

In an embodiment, conditions for processing of the semiconductor substrate with the defluorination plasma include an exposure time of greater than about 5 seconds, for example, about 30 seconds, and an RF power of greater than about 50 watts, for example, about 200 watts. In an embodiment, higher RF levels (e.g., about 400 watts or about 600 watts) may provide acceptable discoloration prevention, while lower RF levels (e.g., about 200 watts) may provide better results with respect to preventing discoloration for wafers exposed to air for extended periods of time before subsequent processing in which the copper surface is covered with additional layers. That is, following post etch treatment at higher RF levels, minor copper discoloration may be present, i.e., upon prolonged exposure of the copper surface to air (e.g., for one hour), while at lower RF levels, copper discoloration may be substantially completely prevented, i.e., upon prolonged exposure of the copper surface to air (e.g., for one hour). Without wishing to be bound by any theories, it is believed that higher RF levels may result in greater changes to the surface morphology (i.e., morphology) of the copper surfaces, as compared to lower RF levels.

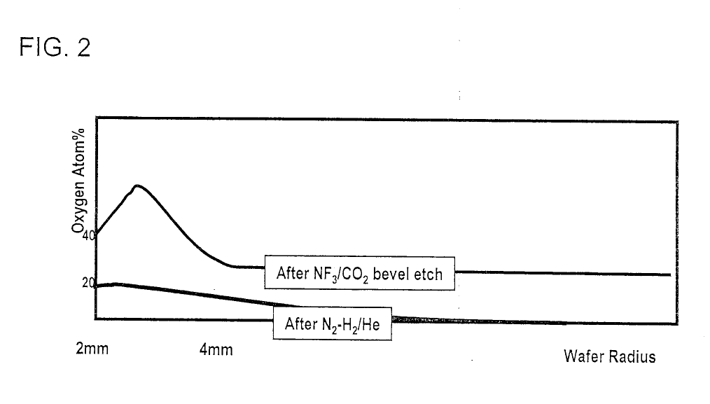

FIG. 2 is a graph showing atomic oxygen content on a copper surface (i.e., a blanket copper layer) of a semiconductor wafer exposed to air for more than seventy-two hours as a function of the wafer radius after NF₃/CO₂ bevel etch processing, N₂—H₂/He processing, and exposure to air for more than seventy-two hours. As illustrated by the graph, the atomic oxygen content on the copper surface of the semiconductor wafer was higher at all points along the wafer radius after NF₃/CO₂ bevel etch processing than after N₂—H₂/He processing.

While various embodiments have been described, it is to be understood that variations and modifications may be resorted to as will be apparent to those skilled in the art. Such variations and modifications are to be considered within the purview and scope of the claims appended hereto.

What is claimed is:

1. A method of bevel edge etching a semiconductor substrate having exposed copper surfaces with a fluorine-containing plasma in a bevel etcher in which the semiconductor substrate is supported on a semiconductor substrate support, comprising:
bevel edge etching the semiconductor substrate with the fluorine-containing plasma in the bevel etcher;
evacuating the bevel etcher after the bevel edge etching is completed;
flowing defluorinating gas into the bevel etcher;
energizing the defluorinating gas into a defluorination plasma at a periphery of the semiconductor substrate; and
processing the semiconductor substrate with the defluorination plasma under conditions to prevent discoloration of the exposed copper surfaces of the semiconductor substrate, the discoloration occurring upon prolonged exposure to air.

2. The method of claim 1, wherein the defluorinating gas comprises hydrogen-containing gas selected from the group consisting of H₂, NH₃, CHₓ, where x is 1-8, and mixtures thereof.

3. The method of claim 1, wherein the defluorinating gas comprises a carrier gas selected from the group consisting of nitrogen, argon, helium, xenon, krypton, and mixtures thereof.

4. The method of claim 1, wherein the defluorinating gas is free of fluorine and oxygen.

5. The method of claim 1, comprising flowing about 10-2000 sccm of defluorinating gas into the bevel etcher.

6. The method of claim 1, comprising flowing a gas mixture of about 100-400 sccm of N₂ and about 200-1000 sccm of 2-10% H₂ in He into the bevel etcher.

7. The method of claim 1, comprising flowing a gas mixture of about 150-250 sccm of N₂ and about 450-550 sccm of 2-10% H₂ in He into the bevel etcher.

8. The method of claim 1, wherein the bevel edge etching comprises energizing a gas comprising NF₃ or CF₄ into the fluorine-containing plasma.

9. The method of claim 1, wherein the bevel edge etching comprises flowing inert gas into the bevel etcher at a center of the semiconductor substrate and flowing fluorine-containing gas into the bevel etcher at a periphery of the semiconductor substrate.

10. The method of claim 1, comprising flowing defluorinating gas into the bevel etcher at a periphery of the semiconductor substrate.

11. The method of claim 1, comprising flowing defluorinating gas into the bevel etcher at a center of the semiconductor substrate and flowing the defluorinating gas radially from the center of the semiconductor substrate towards a periphery of the semiconductor substrate.

12. The method of claim 1, comprising flowing up to 50 volume % of the defluorinating gas into the bevel etcher at a periphery of the semiconductor substrate and greater than or equal to 50 volume % of the defluorinating gas into the bevel etcher at a center of the semiconductor substrate.

13. The method of claim 1, comprising:
processing the semiconductor substrate with the defluorination plasma for up to about 15 seconds; and
generating the defluorination plasma by supplying RF power to a pair of ring electrodes located at the bevel edge and processing the semiconductor substrate with the defluorination plasma at an RF power of greater than about 50 watts.

14. The method of claim 1, comprising:
processing the semiconductor substrate with the defluorination plasma for up to about 30 seconds; and
generating the defluorination plasma by supplying RF power to a pair of ring electrodes located at the bevel edge and processing the semiconductor substrate with the defluorination plasma at an RF power of at least about 200 watts.

15. The method of claim 1, comprising:
processing the semiconductor substrate with the defluorination plasma for up to about 300 seconds; and
generating the defluorination plasma by supplying RF power to a pair of ring electrodes located at the bevel edge and processing the semiconductor substrate with the defluorination plasma at an RF power of at least about 400 watts.

16. The method of claim 1, wherein the semiconductor substrate has a diameter of about 300 mm.

17. The method of claim 1, wherein:
the copper surfaces comprise copper surfaces on tantalum-containing seed layers; and
the bevel edge portion is free of exposed copper surfaces.

18. The method of claim 1, further comprising:
purging the bevel etcher with an inert gas following evacuation of the fluorine-containing plasma from the bevel etcher and before flowing defluorinating gas into the bevel etcher.

19. The method of claim 1, further comprising:
removing the semiconductor substrate from the bevel etcher and exposing the copper surfaces to air,
wherein the copper surfaces are not discolored upon exposure to air for two hours.

20. The method of claim 1, wherein:
bevel edge etching with the fluorine-containing plasma results in fluorine on the copper surfaces; and
processing the semiconductor substrate with a hydrogen-containing defluorination plasma results in hydrogen reacting with fluorine on the copper surfaces and liberating fluorine from the copper surfaces;
wherein fluorine liberated from the copper surfaces is evacuated from the bevel etcher during processing with the defluorination plasma.
